(19) United States
(12) Patent Application Publication
(10) Pub. No.: US 2019/0087039 A1
(43) Pub. Date: Mar. 21, 2019

(54) TOUCH DISPLAY DEVICE AND MANUFACTURING METHOD THEREOF

(71) Applicants: Interface Technology (ChengDu) Co., Ltd., Sichuan (CN); Interface Optoelectronics (ShenZhen) Co., Ltd., Guangdong (CN); General Interface Solution Limited, Miaoli County (TW)

(72) Inventors: Chih-Peng CHANG, Guangdong (CN); Chun-Ming CHEN, Guangdong (CN); Tzu-Hsiang LIN, Guangdong (CN)

(21) Appl. No.: 15/854,709

(22) Filed: Dec. 26, 2017

(30) Foreign Application Priority Data
Sep. 15, 2017 (CN) 201710833324.7

(51) Int. Cl. G06F 3/041; H01L 27/32; H01L 51/52; G06F 3/044

(52) U.S. Cl. CPC G06F 3/0412; H01L 27/323; H01L 27/3244; G06F 2203/04112; G06F 3/044; G06F 2203/04103; H01L 51/5237

(57) ABSTRACT

A touch display device is provided and includes a substrate, a light absorbing layer, a first metal mesh layer, an insulating layer, and a second metal mesh layer. The light absorbing layer is disposed on the substrate. The first metal mesh layer is disposed on the light absorbing layer. The insulating layer is disposed on the substrate and covers the first metal mesh layer and the light absorbing layer. The second metal mesh layer is located at a side of the insulating layer distal to the first metal mesh layer.

### CROSS-REFERENCE TO RELATED APPLICATION

This application claims priority to Chinese Application Serial Number 201710833324.7, filed Sep. 15, 2017, which is herein incorporated by reference.

### BACKGROUND

### Field of Invention

The present disclosure relates to a touch display device and a manufacturing method of the touch display device. More particularly, the present disclosure relates to a touch display device including a light absorbing layer.

### Description of Related Art

A conventional touch display device has a complicated metal mesh fabrication process, and interfered processes for manufacturing a display module and a touch module, thus resulting in a low yield. Additionally, the metal mesh has a light reflection problem that causes an undesirable visual effect. Hence, how to simplify the manufacturing methods, improve the yield, and overcoming the light reflecting problem are important technical issues in the industry.

### SUMMARY

An aspect of the disclosure is to provide a touch display device including a substrate, a light absorbing layer, a first metal mesh layer, an insulating layer, and a second metal mesh layer. The light absorbing layer is disposed on the substrate. The first metal mesh layer is disposed on the light absorbing layer. The insulating layer is disposed on the substrate and the insulating layer covers the first metal mesh layer and the light absorbing layer. The second metal mesh layer is located at a side of the insulating layer distal to the first metal mesh layer.

In some embodiments, the first metal mesh layer has plural first openings, and any two adjacent ones of the first openings has different sizes or shapes.

In some embodiments, the light absorbing layer has plural light transmissive openings, and the light transmissive openings are aligned with the first openings respectively.

In some embodiments, the touch display device further includes a display module disposed on the insulating layer, and in which the second metal mesh layer is located in the display module.

In some embodiments, the display module includes plural light sources, and the second metal mesh layer includes plural second openings. The light sources are aligned with the second openings respectively.

In some embodiments, the display module further includes a packaging layer connected to the insulating layer, and the second metal mesh layer is disposed at a side of the packaging layer distal to the insulating layer.

Another aspect of the disclosure is to provide a manufacturing method of touch display device, the manufacturing method includes: disposing a light absorbing layer on a substrate; disposing a first metal mesh layer on the light absorbing layer; disposing an insulating layer on the substrate to cover the first metal mesh layer and the light absorbing layer; and forming a display module on the insulating layer, in which the display module includes a second metal mesh layer.

In some embodiments, the disposing the light absorbing layer on the substrate is performed by a plating process or a transfer printing process, and plural light transmissive openings are formed in the light absorbing layer.

In some embodiments, the disposing the first metal mesh layer on the substrate is performed by a plating process or a transfer printing process, and plural first openings are formed in the first metal mesh layer.

Another aspect of the disclosure provides a manufacturing method of touch display device, the manufacturing method includes: forming a light absorbing layer on the substrate; forming a first metal mesh layer on the light absorbing layer; and attaching the substrate to a display module by an adhesive layer, in which the display module includes a second metal mesh layer.

In some embodiments, forming the light layer on the substrate is performed by a plating process or a transfer printing process, and plural light transmissive openings are formed in the light absorbing layer.

In some embodiments, forming the first metal mesh layer on the substrate is performed by a plating process or a transfer printing process, and plural first openings are formed in the first metal mesh layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a schematic cross-sectional view of a touch display device according to an embodiment of the present disclosure;

FIG. 2a to FIG. 2d illustrate schematic cross-sectional views of a touch display device at various manufacturing stages according to an embodiment of the present disclosure;

FIG. 3 illustrates a flow chart of a manufacturing method of a touch display device according to an embodiment of the present disclosure;

FIG. 4 illustrates a touch display device according to an embodiment of the present disclosure;

FIG. 5 illustrates a diagram showing a process step in a manufacturing method of a touch display device; and

FIG. 6 illustrates a flow chart of a manufacturing method of a touch display device according to another embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

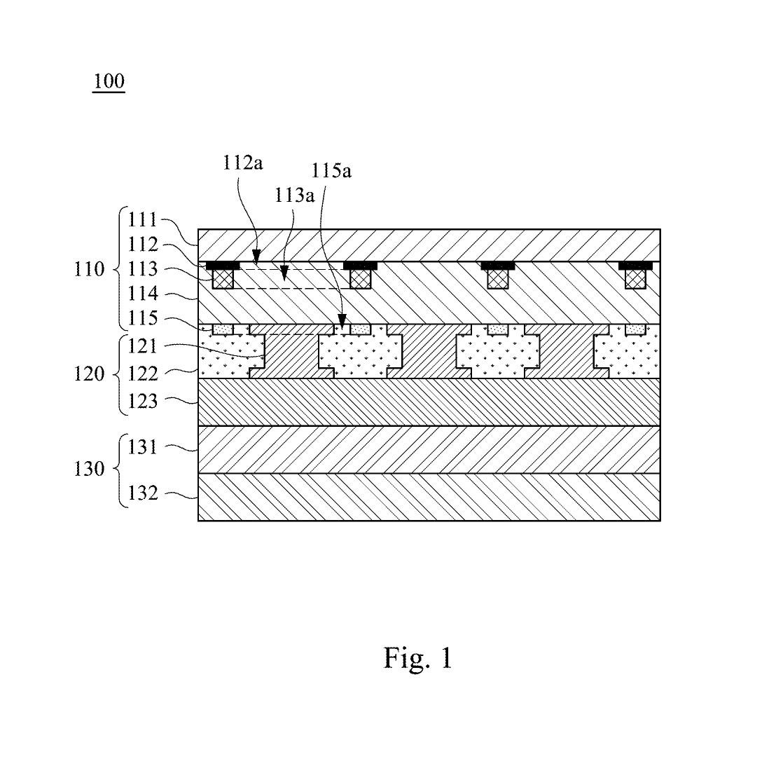

Please refer to FIG. 1. FIG. 1 illustrates a schematic cross-sectional view of a touch display device according to an embodiment of the present disclosure. As shown in FIG. 1, a touch display device 100 includes a touch module 110 and a display module 120. In the embodiment of FIG. 1, the touch module 110 includes a substrate 111, a light absorbing layer 112, a first metal mesh layer 113, an insulating layer 114, and a second metal mesh layer 115. The display module 120 includes light sources 121, a filling layer 122, and a TFT (thin film transistor) layer 123.

As shown in FIG. 1, the light absorbing layer 112 is disposed on the substrate 111 of the touch module 110, and a first metal mesh layer 113 is disposed on the light absorbing layer 112. The light absorbing layer 112 is made of CuO, C, or another black matrix material such as black photoresist and black matrix resist, thereby shielding incident light above the substrate 111. As a result, the light absorbing layer 112 prevents the incident light from being reflected by the first metal mesh layer 113, thus overcoming the visual defects caused by the reflected light.

As shown in FIG. 1, the light absorbing layer 112 has plural light transmissive openings 112a, and the first metal mesh layer 113 has plural first openings 113a. The light transmissive openings 112a are connected with the first openings 113a respectively. In the embodiment of FIG. 1, the light transmissive openings 112a are smaller than the first openings 113a. That is to say, if the touch display device 100 is viewed from above the substrate 111, the light absorbing layer 112 may entirely shield the first metal mesh layer 113, so as to achieve better shielding performance. But in some embodiments, the light transmissive openings 112a are larger than the first openings 113a. That is to say, if the touch display device 100 is viewed from above the substrate 111, the light absorbing layer 112 cannot entirely shield the first metal mesh layer 113, so as to achieve better light transmittance.

In the embodiment of FIG. 1, each of the first openings 113a has a different contour shape. That is to say, grids of the first metal mesh layer 113 are not substantially regular in shape. The structural irregularity of the first metal mesh layer 113 enhances scattering effects of light, and thus the incident light above the substrate 111 may not be reflected by the first metal mesh layer 113. As a result, the metal luster of the touch display device 100 is reduced, and the overall visual effect is enhanced.

As shown in FIG. 1, the second metal mesh layer 115 is disposed on the insulating layer 114, and the second metal mesh layer 115 has plural second openings 115a. The second openings 115a are aligned with the first openings 113a respectively, such that the second metal mesh layer 115 and the first metal mesh layer 113 are matched to form a sensor layer with touch function.

In the embodiment of FIG. 1, the first metal mesh layer 113 and second metal mesh layer 115 are separated by an insulating layer 114. The insulating layer 114 may be made of various transparent dielectric materials, such as optical clear (OC) materials, transparent photosensitive film (TPF), or any other transparent material that can electrically separate the first metal mesh layer 113 from the second metal mesh layer 115. In some embodiments, the thickness of the insulating layer 114 is less than 15 um.

As shown in FIG. 1, the display module 120 of the touch display device 100 is disposed on the insulating layer 114, and the second metal mesh layer 115 of the touch module 110 is embedded in the display module 120. In the embodiment of FIG. 1, the display module 120 includes plural light sources 121, for example, each of the light sources 121 is an organic light-emitting diode (OLED) that can emit light of various colors. As shown in FIG. 1, the light sources 121 are aligned with the second openings 115a respectively, so that the light emitted by the light sources 121 may pass through the second openings 115a, the first openings 113a and the light transmissive openings 112a in order, thus enabling the touch display device 100 to exhibit a color picture. A filling layer 122 fills between every two adjacent light sources 121. For example, the filling layer 122 may be made of resin. The filling layer 122 may protect the light sources 121 from being dampened, physical damaged, changed in chemical properties, and so on.

As shown in FIG. 1, the TFT layer 123 is disposed at a side of the light sources 121 distal to the insulating layer 114. The TFT layer 123 may determine the on and off of each light source 121 according to signals from an external processor. For example, the TFT layer 123 includes plural scan lines and data lines. The scan lines are connected to a row of transistor gates respectively and the data lines are connected to a column of transistor sources respectively, and thus each transistor is corresponding to a set of scan and data lines. When an external processor provides a voltage difference to the set of scan and data lines, the transistor corresponding to the set of scan and data line will be activated and drives the corresponding light source 121 to emit light.

As shown in FIG. 1, the touch display device 100 further includes a material layer 130. The material layer 130 includes an adhesive layer 131 and a holding layer 132. By use of the adhesive layer 131, the holding layer 132 is attached to a side of the TFT layer 123 distal to the light sources 121. The holding layer 132 provides physical and chemical protection to the touch display device 100, thereby preventing the touch display device 100 from being damaged by ambiance in manufacturing, assembling, or transferring process. For example, the holding layer 132 may be made of PET (polyethylene terephthalate), PI (polyimide), PEN (polyethylene napthalene), or PC (polycarbonate), and the adhesive layer 131 may be made of optical clear adhesive (OCA). It should be realized that the composition, properties may be modulated properly according to practical needs for manufacturing, products purpose, transportation, or so on. In another embodiment of the present disclosure, the material layer 130 may be an insulating layer, a packaging layer or a plastic thin film, or any appropriate layer having an insulating or protecting effect.

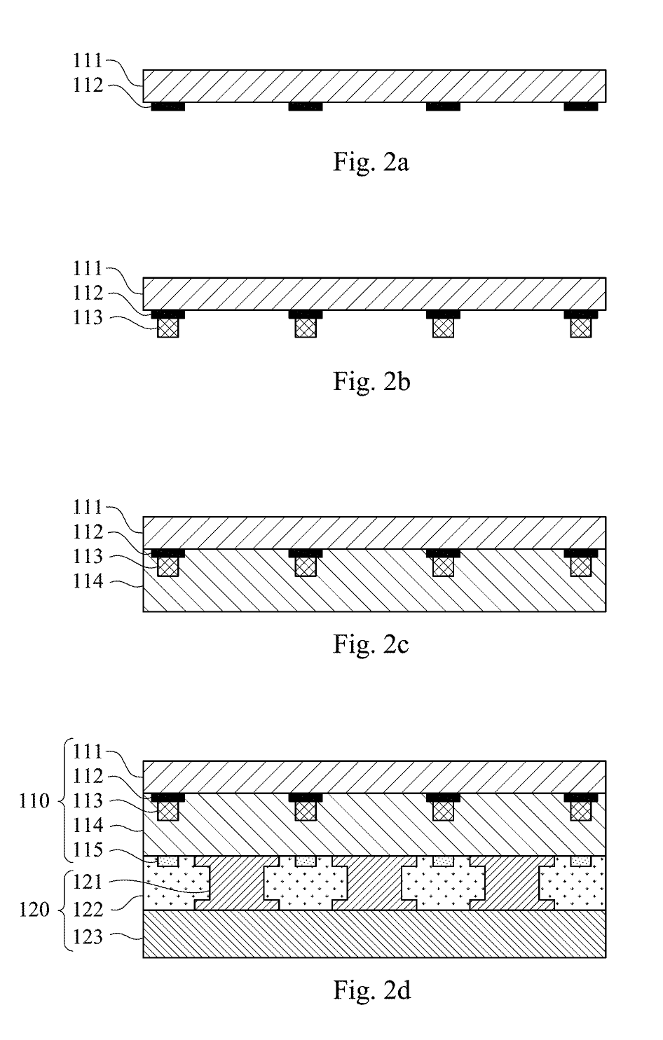

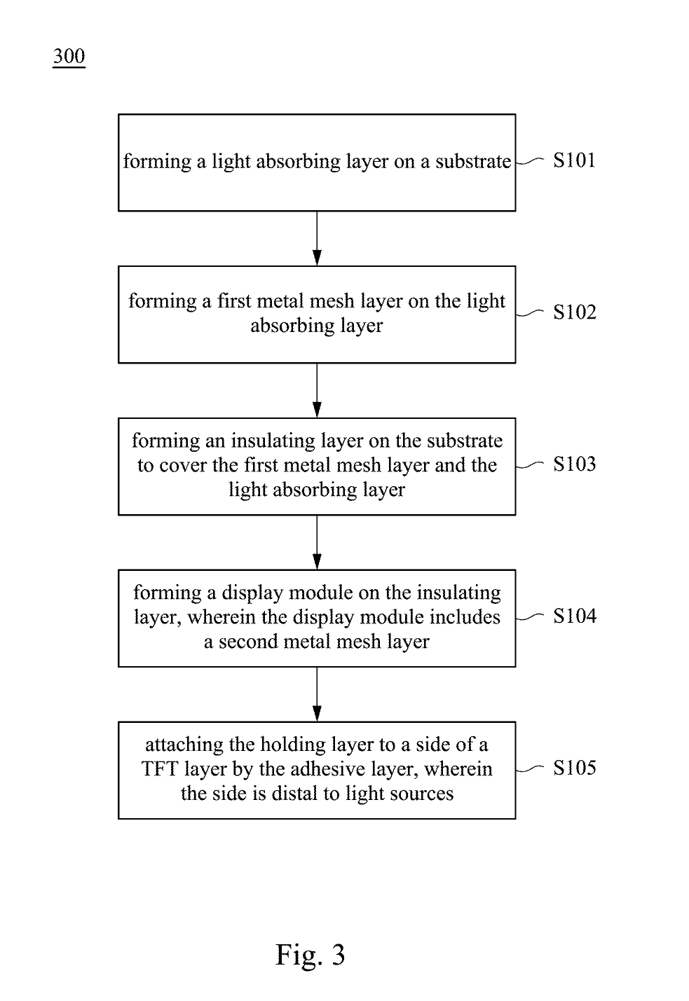

One embodiment is disclosed with reference to FIG. 1 as aforementioned. Another aspect of the present disclosure relates to a manufacturing method of the touch display device 100, which will be described with reference to FIG. 2a to FIG. 2d and FIG. 3 as follows.

Please refer to FIG. 2a to FIG. 2d and FIG. 3. FIG. 2a to FIG. 2d illustrate schematic cross-sectional views of the touch display device 100 at various manufacturing stages according to an embodiment of the present disclosure. FIG. 3 illustrates a flow chart of the manufacturing method of the touch display device 100 according to an embodiment of the present disclosure.

Please refer to FIG. 2a and FIG. 3. In step S101 of the touch display device manufacturing method 300, a light absorbing layer 112 is formed on a substrate 111. For example, a transfer printing process, a plating process, an etching process, a depositing process, or an epitaxy process may be performed to form the light absorbing layer 112 on the substrate 111 and form plural light transmissive openings 112a within the light absorbing layer 112. For example, in some embodiments, the light absorbing layer 112 with a desire thickness is deposited by the depositing process, and then the etching process is performed to form the light transmissive openings 112a. For example, in some embodiments, the transfer printing process, the plating process, or the epitaxy process is performed to directly form the light absorbing layer 112 with multiple light transmissive openings 112a.

Please refer to FIG. 2b and FIG. 3. After step S101, step S102 is performed. In step S102, a first metal mesh layer 113 is formed on the light absorbing layer 112. For example, a transfer printing process, a plating process, an etching process, a depositing process, or an epitaxy process is performed to form the first metal mesh layer 113 on the light absorbing layer 112, in which plural first openings 113a are formed within the first metal mesh layer 113. For example, in some embodiments, the first metal mesh layer 113 with a desire thickness is deposited on the light absorbing layer 112 and the substrate 111 by the depositing process, and then the first openings 113a are formed by the etching process. For example, in some embodiments, the transfer printing process, the plating process, or the epitaxy process is performed to directly form the first metal mesh layer 113 with multiple first openings 113a. The first metal mesh layer 113 formed by the transfer printing process or plating process will have an irregular grid contour.

Please refer to FIG. 2c and FIG. 3. After step S102, step S103 is performed. In step S103, the insulating layer 114 is formed on the substrate 111 to cover the light absorbing layer 112 and the first metal mesh layer 113. For example, the insulating layer 114 may be deposited on the substrate 111 by a depositing process.

Please refer to FIG. 2d and FIG. 3. After step S103, step S104 is performed. In step S104, a second metal mesh layer 115 is formed on the insulating layer 114, and plural second openings 115a are formed within the second metal mesh layer 115. For example, a transfer printing process, a plating process, an etching process, a depositing process, or an epitaxy process may be performed to form the second metal mesh layer 115. The method of forming the second metal mesh layer 115 is similar to that of forming the first metal mesh layer 113, and thus is not repeated herein. It should be realized that the method of forming the second metal mesh layer 115 and that of forming the first metal mesh layer 113 may be the same or different. After the second openings 115a are formed, each light source 121 is disposed at a location corresponding to one of the second openings 115a, and then a filling layer 122 is formed between every two adjacent light sources 121, and the TFT layer 123 is formed at a side of the light sources 121 distal to the insulating layer 114. In some embodiments, the filling layer 122 may be resin.

Please refer to FIG. 1 and FIG. 3. After step S104, step S105 is performed. In step S105, an adhesive layer 131 is used to attach a holding layer 132 at a side of the TFT layer 123 distal to the light sources 121. After step S105, the resulting structure is the touch display device 100 as shown in FIG. 1. The manufacturing method 300 of the touch display panel is completely disclosed with reference to step S101 to step S105, and thus people with ordinary skills in the art should be able to manufacture the touch display device 100.

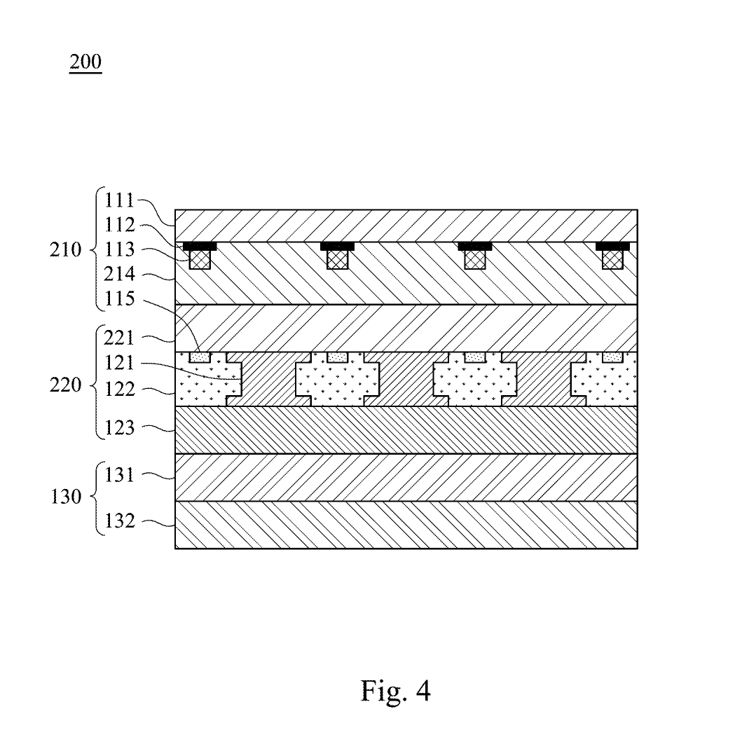

Please refer to FIG. 4. FIG. 4 illustrates a touch display device 200 according to an embodiment of the present disclosure. The difference between the touch display device 200 and the touch display device 100 is that a display module 220 of the touch display device 200 further includes a packaging layer 221, and a touch module 210 in FIG. 4 is similar to the touch module 110 shown in FIG. 1 by replacing the insulating layer 114 with an adhesive layer 214. The packaging layer 221 is connected to the adhesive layer 214, and the second metal mesh layer 115 of the touch module 210 is disposed at a side of the packaging layer 221 distal to the adhesive layer 214. That is, the second metal mesh layer 115 is formed within the display module 220. Compositions and relative relationships of other elements are similar to those of the touch display device 100 shown in FIG. 1, and thus are not repeated herein.

In the embodiment shown in FIG. 4, the adhesive layer 214 may be made of a material such as OCA, or another adhesive material with insulating property. The packaging layer 221 may be made of resin, or another materials having protecting property. In some embodiments, the thickness of the adhesive layer 214 is less than 50 um.

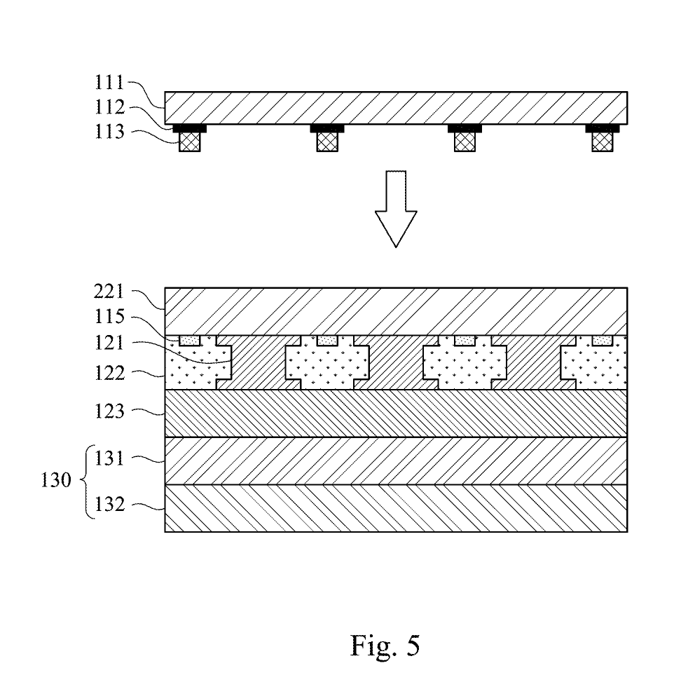

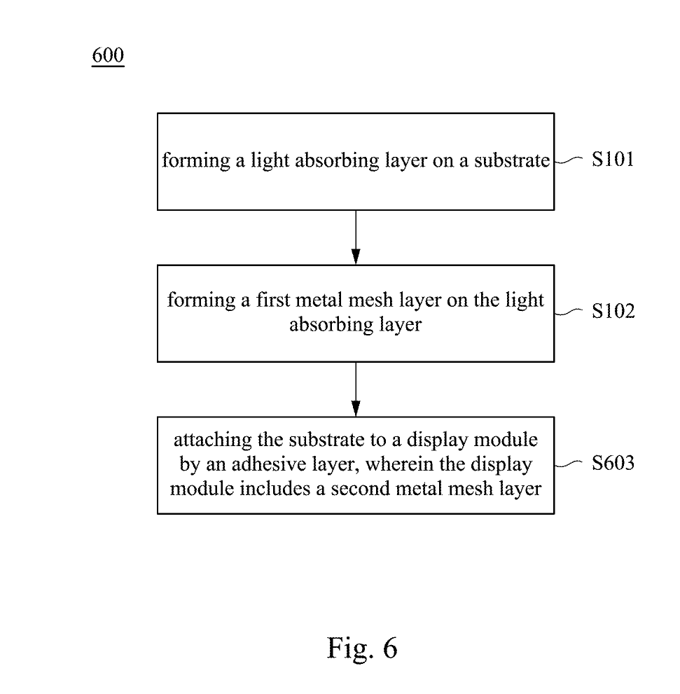

One of the embodiments of the present disclosure is described with reference to FIG. 4 as mentioned above. Another aspect of the present disclosure relates to the manufacturing method of the touch display device 200 which is described with reference to FIG. 5 and FIG. 6 as follows.

Please refer to FIG. 5 and FIG. 6. FIG. 5 illustrates a diagram showing a process step in a manufacturing method 600 of the touch display device. FIG. 6 illustrates a flow chart showing the manufacturing method of the touch display device 200 according to an embodiment of the present disclosure.

As shown in FIG. 6, the first two steps of the manufacturing method 600 are step S101 and step S102 respectively, which are the same as the first two steps of the manufacturing method 300, and thus are not repeated herein. The difference between the manufacturing method 600 and the manufacturing method 300 is that, after step S101 and step S102, the manufacturing method 600 is followed by step S603.

As shown in FIG. 5, in step S603, by using an adhesive layer 214, the substrate 111 disposed with first metal mesh layer 113 and light absorbing layer 112 is attached to a packaging layer 221 of a display module 220 that has been fabricated, and the resulting structure is the touch display device 200 as shown in FIG. 4. In some embodiments, the alignment accuracy of the attaching device is less than 5 um.

In the manufacturing method 600 shown in FIG. 6, the touch module 210 and the display module 220 are manufactured separately, and thus the manufacturing steps of both would not interfere with each other. In sum, the yield of the touch display device 200 is improved and the loss is decreased by the touch display device manufacturing method 600.

In sum, the present disclosure provides a touch display device and a manufacturing method thereof. The light absorbing layer can reduce the reflect light that will cause undesired visual effects, and the irregular grid of the metal mesh layer can enhance the scattering effect of the incident light. Thus, the metal luster of the touch display device is reduced and the overall visual effect is improved. The manufacturing method of the touch display device provides the irregularity of the metal mesh layer that may be formed by the plating or transfer printing process. The plating and transfer printing process are both simpler than the conventional manufacturing method of the touch display device, thus greatly simplifying the conventional manufacturing method. The manufacturing method of the touch display device of the present disclosure also provides the display module and the touch module that may be manufactured separately, so as to overcome the issue that various manufacturing steps would interfere with each other, thus improving the yield of products.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A touch display device, comprising:
a substrate;
a light absorbing layer disposed on the substrate;
a first metal mesh layer disposed on the light absorbing layer;
an insulating layer disposed on the substrate and covering the first metal mesh layer and the light absorbing layer; and
a second metal mesh layer located at a side of the insulating layer that is distal to the first metal mesh layer.

2. The touch display device of claim 1, wherein the first metal mesh layer has a plurality of first openings, and any two adjacent ones of the first openings has different sizes or shapes.

3. The touch display device of claim 2, wherein the light absorbing layer has a plurality of light transmissive openings, and the light transmissive openings are aligned with the first openings respectively.

4. The touch display device of claim 1, further comprising a display module disposed on the insulating layer, wherein the second metal mesh layer is located in the display module.

5. The touch display device of claim 4, wherein the display module comprises a plurality of light sources and the second metal mesh layer comprises a plurality of second openings, wherein the light sources are aligned with the second openings respectively.

6. The touch display device of claim 4, wherein the display module further comprises a packaging layer connected to the insulating layer, and the second metal mesh layer is disposed at a side of the packaging layer that is distal to the insulating layer.

7. A manufacturing method of touch display device, the manufacturing method comprising:
forming a light absorbing layer on a substrate;
forming a first metal mesh layer on the light absorbing layer;
forming an insulating layer on the substrate to cover the first metal mesh layer and the light absorbing layer; and
forming a display module on the insulating layer, wherein the display module comprises a second metal mesh layer.

8. The manufacturing method of claim 7, wherein the forming the light absorbing layer on the substrate is performed by a plating process or a transfer printing process, and forms a plurality of light transmissive openings in the light absorbing layer.

9. The manufacturing method of claim 7, wherein the forming the first metal mesh layer on the substrate is performed by a plating process or a transfer printing process, and forms a plurality of first openings in the first metal mesh layer.

10. A manufacturing method of a touch display device, the manufacturing method comprising:
forming a light absorbing layer on a substrate;
forming a first metal mesh layer on the light absorbing layer; and
attaching the substrate to a display module by an adhesive layer, wherein the display module comprises a second metal mesh layer.

11. The manufacturing method of claim 10, wherein the forming the light absorbing layer on the substrate is performed by a plating process or a transfer printing process, and forms a plurality of light transmissive openings in the light absorbing layer.

12. The manufacturing method of claim 10, wherein the forming the first metal mesh layer on the substrate is performed by a plating process or a transfer printing process, and forms a plurality of first openings in the first metal mesh layer.
